(19) United States
(12) Patent Application Publication
(10) Pub. No.: US 2007/0262297 A1
(43) Pub. Date: Nov. 15, 2007

(54) Organic thin-film transistor device and corresponding manufacturing method

(76) Inventors: Salvatore Leonardi, Aci S. Antonio (CT) (IT); Claudia Caligiore, Giarre (CT) (IT); Guglielmo Fortunato, Roma (IT); Luigi Mariucci, Roma (IT); Stefano Cipolloni, Benedetto del Tronto (AP) (IT); Francesco De Angelis, Roma (IT)

Correspondence Address: GRAYBEAL, JACKSON, HALEY LLP, 155 - 108TH AVENUE NE, SUITE 350, BELLEVUE, WA, 98004-5973, US

(21) Appl. No.: 11/432,760

(22) Filed: May 10, 2006

(51) Int. Cl. H01L 29/08; H01L 35/24; H01L 51/00

(52) U.S. Cl. 257/40

(57) ABSTRACT

An organic thin-film transistor device integrated on a substrate and comprising at least an organic active layer and metallic contact regions realized on an insulating layer. Advantageously the organic thin-film transistor device further comprises a thin buffer layer of polymethylmetacrylate or PMMA realized between the metallic contact regions and the organic active layer. A process for manufacturing an organic thin-film transistor device is also described.

### TECHNICAL FIELD

The present invention relates generally to an organic thin-film transistor (O-TFT) device.

More specifically, an embodiment of the invention relates to an organic thin-film transistor device integrated on a substrate and including at least an organic active layer and metallic contact regions realized on an insulating layer.

Another embodiment of the invention further relates to a process for manufacturing an organic thin-film transistor device on a substrate.

### BACKGROUND

As it is well known, in recent years there has been a growing interest in organic thin-film transistors, usually indicated as O-TFT device. This increased interest is mainly due to attractive features of these kind of transistors, such as low cost, low-temperature processing, and mechanical flexibility, the former being essentially linked to the use of organic materials, cheaper than the integrated inorganic ones.

O-TFT devices have been realized on a variety of substrates, including silicon, glass, or plastics, and different organic active layers have been investigated, as described in the following articles:
[1] H. Klauk, M. Halik, U. Zschieschang, G. Schimd, W. Radik, and W. Weber, “High-mobility polymer gate dielectric pentacene thin film transistors”, J. Appl. Phys. 92, 5259 (2002);
[2] H. Klauk, M. Halik, U. Zschieschang, F. Eder, G. Schimd, and C. Dehm, “Pentacene organic transistors and ring oscillators on glass and on flexible polymeric substrates”, Appl. Phys. Lett. 82, 4275 (2003);
[3] Y. Kato, S. Iba, R. Teramoto, T. Sekitani, T. Someya, H. Kawaguchi, and T. Sakurai, “High mobility of pentacene field-effect transistors with polyimide gate dielectric layers”, Appl. Phys. Lett. 84, 3789 (2004);
[4] C. J. Drury, C. M. J. Mutsaers, C. M. Hart, M. Matters, and D. M. de Leeuw, “Low-cost all-polymer integrated circuits”, Appl. Phys. Lett. 73, 108 (1998);
[5] F. Eder, H. Klauk, M. Halik, U. Zschieschang, G. Schimd, and C. Dehm, “Organic electronics on paper”, Appl. Phys. Lett. 84, 2673 (2004);
[6] T. Minari, T. Nemoto, and S. Isoda, “Fabrication and characterization of single-grain organic field-effect transistor of pentacene”, J. Appl. Phys. 96, 769 (2004);
[7] J. Lee, K. Kim, J. H. Kim, and S. Im, “Optimum channel thickness in pentacene-based thin-film transistors”, Appl. Phys. Lett. 82, 4169 (2003);
[8] F. De Angelis, T. Toccoli, A. Pallaoro, N. Coppedè, L. Mariucci, G. Fortunato, and S. Iannotta, “SuMBE based organic thin film transistors”, Synth. Met. 146, 291 (2004);
[9] D. Knipp, R. A. Street, A. Volkel, and J. Ho, “Pentacene thin film transistors on inorganic dielectrics: Morphology, structural properties, and electronic transport”, J. Appl. Phys. 93, 347 (2003); and
[10] V. Podzorov, V. M. Pudalov, and M. E. Gershenson, “Field-effect transistors on rubrene single crystals with parylene gate insulator”, Appl. Phys. Lett. 82, 1739 (2003).

It is also known in the field that pentacene is the organic layer which realizes an active layer having good performance.

Moreover, the performance of such O-TFT devices are dependent on their gate structure, and more particularly, to the material to be used for forming the gate insulator layer.

Different dielectric materials can be employed as a gate insulator layer, both inorganic [such as, SiO₂, Si₃N₄, Al₂O₃] and organic [such as poly(4-vinylphenol) (PVP), polyimide, parylene, polyaniline (PANI)].

Recent works have shown that using organic dielectrics as gate insulator layer, very high values for the field-effect mobility of the O-TFT device have been obtained, even higher than those obtained with inorganic dielectrics as gate insulator layers, although inorganic dielectric materials provide lower leakage current and lower hysteresis.

The best solution for an O-TFT device nowadays is a pentacene-based thin-film transistor coupled with both inorganic and organic gate dielectrics.

However, it has also been found that the interaction of π-conjugated pentacene with metal contact or gate dielectric surfaces, strongly affects the growth process and affects the morphology of the organic film so realized.

Referring to FIG. 1, it should be considered that this is a main problem when considering an O-TFT device 10 having a bottom contact or BC configuration.

The O-TFT device 10 comprises a thick oxide protective layer 1 whereon a gate region 2 is formed, as well as a gate insulating layer 3, the latter covering both the gate region 2 and the thick oxide protective layer 1.

On the gate insulating layer 3 a drain contact region 4 and a source contact region 5 are then realized, spaced apart from each other and define therebetween a intermediate region 3A of the gate insulating layer 3 which is substantially aligned with the gate region 2.

The O-TFT device 10 further comprises an organic active layer 6, preferably a pentacene layer, which is deposited over the drain and source contact regions, 4 and 5, as well as over the gate insulating layer 3 in correspondence with the intermediate region 3A.

The O-TFT device 10 is then completed by a buffer layer 7 realized on the organic active layer 6, which a corresponding profile, and a final layer 8, usually made of an optical resist and also used to planarize the final device so obtained.

It has been discovered that in this kind of O-TFT device having a BC configuration, the polycrystalline pentacene of the organic active layer 6 degrades in an amorphous phase along boundaries of the drain and source contact regions, 4 and 5, decreasing the performance of the O-TFT device 10.

This known problem is reduced by using thin buffer layer 9 made of a monolayer of octadecyltrichlorosilane (OTS) and realized on the drain and source regions, 4 and 5, as well on the intermediate region 3A of the gate insulating layer 3 before the organic active layer 6 is deposited. In fact, it has been demonstrated that the interaction of the π-conjugated links with interfaces are thus decreased.

Referring to FIG. 2, also known are O-TFT devices 20 having a top contact or TC configuration.

For corresponding layers with respect to the O-TFT device 10 described with reference to FIG. 1, same reference numbers will be applied.

In particular, the O-TFT device 20 comprises a thick oxide protective layer 1 in which a gate region 2 is formed by doping a corresponding portion of the thick oxide protective layer 1, which is then covered by a gate insulating layer 3.

Moreover, on the gate insulating layer 3, a organic active layer 6, in particular a pentacene layer, is deposited.

Finally a drain contact region 4 and a source contact region 5 are formed on the organic active layer 6.

Due to the integration of the drain and source contact regions, 4 and 5, only after the deposition of the organic active layer 6, the O-TFT device 20 having a TC configuration is normally reported to have better performance with respect to the O-TFT device 10 having a BC configuration.

In particular, pentacene-thin-film transistors with a field-effect mobility of 3 cm²/Vs, without a thin buffer layer 9, have been realized by using a gate insulating layer 3 of PVP. Furthermore, pentacene-thin-film transistors have been realized by using a gate insulating layer 3 of polyimide with a field-effect mobility of 1 cm²/Vs. Such high mobility values can be achieved only through an effective control of the interface between the pentacene layer 6 and the gate insulating layer 3, that allows to reduce defects and grain boundaries.

However, the manufacturing of O-TFT device 20 having a TC configuration is nowadays difficult in an industrial context and not easily repeatable, due to the definition of the contact regions as well as of the terminal region of the integrated device so obtained on a pentacene layer.

In conclusion, O-TFT devices 20 having a BC configuration are more suitable from an industrial point of view, even if they require a control of the interfaces between pentacene, contact, and gate dielectric layers. In particular, an OTS thin buffer layer 9, which substantially improves the interface quality, can be used only with the dielectric layers that contain hydroxy groups (OH), allowing an OTS monolayer to self-assemble on their surfaces.

### SUMMARY

An embodiment of this invention provides an organic thin-film transistor device showing a good field-effect mobility and reduced manufacturing problems and costs, in this way overcoming the limits which still affect the devices realized according to the prior art.

More specifically, this embodiment of the invention is an organic thin-film transistor device which comprises a thin film of polymethylmetacrylate (PMMA) acting as a buffer layer for an organic active layer of pentacene.

Yet another embodiment of the invention further relates to a process for manufacturing such an organic thin-film transistor device on a substrate.

### BRIEF DESCRIPTION OF THE DRAWINGS

The characteristics and advantages of the organic thin-film transistor and corresponding manufacturing process according to an embodiment of the invention will be apparent from the following description of an embodiment thereof given by way of indicative and non limiting example with reference to the annexed drawings.

In the drawings:

FIG. 1 is a schematic sectional view of an organic thin-film transistor having a bottom contact configuration realized according to the prior art;

FIG. 2 is a schematic sectional view of an organic thin-film transistor having a top contact configuration realized according to the prior art;

FIGS. 3A-3C are schematic sectional views of an organic thin-film transistor having a bottom contacts configuration realized according to an embodiment of the invention in different steps of its manufacturing process;

FIG. 4 is an AFM micrographs of a detail of a pentacene layer of an organic thin-film transistor according to an embodiment of the invention;

FIGS. 5A and 5B are plots of transfer and output characteristics, respectively, of organic thin-film transistors realized according to the prior art and to an embodiment of the invention; and

FIG. 5C is a plot of a normalized transconductance vs gate voltage of organic thin-film transistors realized according to an embodiment of the invention for different channel lengths.

### DETAILED DESCRIPTION

The following discussion is presented to enable a person skilled in the art to make and use the invention. Various modifications to the embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

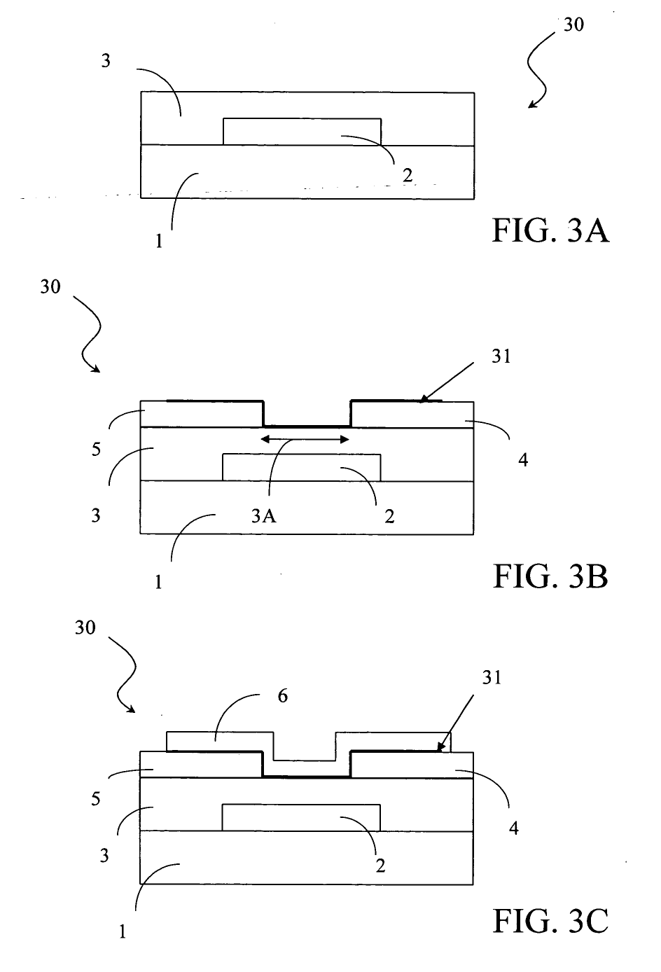

Referring to FIGS. 3A-3C, an organic thin-film transistor or O-TFT device (globally indicated with 30) and its manufacturing process are described according to one embodiment of the present invention.

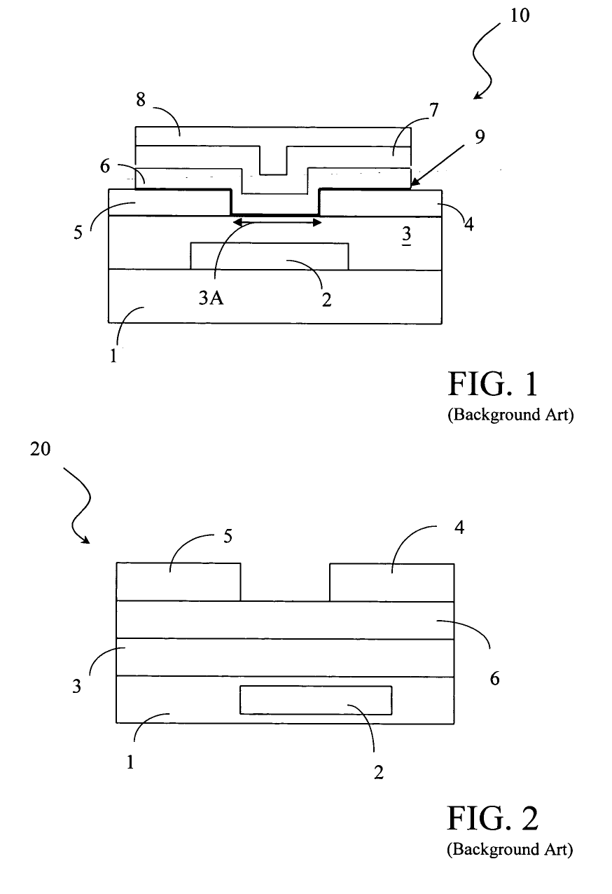

To structurally and/or functionally equal elements, in particular layers, with respect to the O-TFT devices described with reference to FIGS. 1 and 2, same reference numbers will be applied.

The O-TFT device 30 comprises a thick oxide protective layer 1, whereon a gate region 2 is formed, as well as a gate insulating layer 3, the latter covering both the gate region 2 and the thick oxide protective layer 1.

On the gate insulating layer 3, a drain contact region 4 and a source contact region 5 are then realized, spaced apart from each other and define therebetween a intermediate region 3A of the gate insulating layer 3 which is substantially aligned with the gate region 2.

The O-TFT device 30 further comprises an organic active layer 6, preferably a pentacene layer, which is deposited over the drain and source contact regions, 4 and 5, as well as over the gate insulating layer 3 in correspondence with the intermediate region 3A in a top contact configuration for sake of illustration only, an embodiment of the invention also relating to an O-TFT device having a BC configuration, as will be clear from the following description.

Advantageously according to an embodiment of the invention, the O-TFT device 30 comprises a thin buffer layer 31 of polymethylmetacrylate (PMMA), also known as Plexiglass. The PMMA thin buffer layer 31 is realized on the drain and source regions, 4 and 5, as well on the intermediate region 3A of the gate insulating layer 3 before the organic active layer 6 is deposited.

More particularly, the manufacturing process of the organic thin-film transistor according to an embodiment of the invention comprises the following steps.

A first formation step of a thick oxide protective layer 1 on a substrate, made silicon, or glass or other flexible material being suitable handled. It should be noted that embodiments of the present invention also apply to any kind of plastic material to be used to realize such a substrate, only requiring that a temperature whereat the substrate is damaged is not to be reached nor overcame.

In particular, the first formation step comprises a first cleaning step of the substrate to remove any contaminants or undesired particles and a step wherein the thick oxide protective layer 1 is realize, for instance by a ECR-PECVD (Electron Cyclotron Resonance Plasma Enhanced Chemical Vapour Deposition) at 250° C., particularly suitable for plastic substrate. It should be remarked that the thick oxide protective layer 1 acts as a mechanical, electrical and thermal insulation element for the substrate itself.

The process then comprises a step of depositing a metallic layer, for instance made of Au or Cr and having a thickness from 10 to 200 nanometers, preferably 50 nanometers, followed by a step of patterning this metallic layer in order to form the gate region 2.

A second formation step is then carried out on the gate region 2 and on the thick oxide protective layer 1 to form the gate insulating layer 3, by depositing a dielectric material or even by using an organic layer, with a thickness from 10 to 500 nanometers, preferably 100 nanometers, as shown in FIG. 3A.

After a second cleaning step, the process comprises a definition step of the drain contact region 4 and the source contact region 5, in turn comprising a step of deposition (sputtering or evaporating) of a metal layer with a thickness from 10 to 200 nanometers, preferably 20 nanometers, on the gate insulating layer 3, followed by an optical lithography and a wet attack, as shown in FIG. 3B.

Referring to FIG. 3B, advantageously according to an embodiment of the invention, the manufacturing process then comprises an annealing step performed at 120° C. for 30 minutes and followed by a third cleaning step in HF:H₂O=1:80 for 5 seconds followed by an integration step of the PMMA thin buffer layer 31 on the drain and source contact region, 4 and 5, and on the intermediate region 3A of the gate insulating layer 3.

Advantageously, the integration step of the PMMA thin buffer layer 31 comprises a spinning step wherein a layer having a thickness of 5-10 nanometers is formed, followed by an annealing step at 90° C. for 10 minutes.

Referring to FIG. 3C, the process then comprises a step of forming the organic active layer 6, in particular a pentacene layer which is grown on said PMMA thin buffer layer 31.

More particularly, the step of forming the pentacene layer 6 comprises an evaporation step, for instance having an evaporation rate of 0.5-5 nm/min.

In this way, the PMMA thin buffer layer 31 does not enable a direct interface between the pentacene layer 6 and the metallic contact layers of the drain and source contact regions, 4 and 5, thus improving the performances of the organic thin-film transistor so obtained and its correct industrial reproducibility.

The O-TFT device 30 is then completed in a standard way.

It should be remarked that the PMMA thin buffer layer 31 reduces the interaction between a π-conjugated system of a pentacene layer and a metal or dielectric adjacent layer and that it can be used to realize thin-film transistors, both in bottom contact and top contact configuration, such thin-film transistors showing very high field-effect mobility (μ_{FE}=0.65 and 1.4 cm²/Vs, for bottom and top contact configuration, respectively) and a remarkably steep subthreshold region.

More particularly, it can be demonstrated that a PMMA thin buffer layer 31 improves the crystal quality along the metal contacts' boundaries, while still allowing good ohmic contact.

The Applicant has produced bottom and top contact O-TFT devices on heavily doped silicon wafers (acting as gate region 2) with a thermal silicon oxide 120-nm thick (acting as gate insulating layer 3).

More particularly, in a BC configuration, the source and drain contact region 4 and 5 (30-nm thick) have been defined by optical lithography and wet etching with channel lengths L=15, 25, 100, 500 μm and channel width W=200 μm. The samples have been annealed at 120° C. for 30 min, cleaned with HF:H20=1:80 for 5 s, and finally covered by spinning with a film of PMMA 950 K annealed at 90° C. for 10 min (thickness about 8 nm).

Thermal evaporation of pentacene (Sigma Aldrich 97%) has been performed on the samples with or without the PMMA thin buffer layer 31, with no extra purification process or substrate heating (evaporation rate about 3 nm/min, vacuum pressure 3*10⁻⁶ mbar).

Moreover, for a TC configuration, gold source and drain contacts have been evaporated through a shadow mask on top of the pentacene active layer (L=100 μm, W=200 μm).

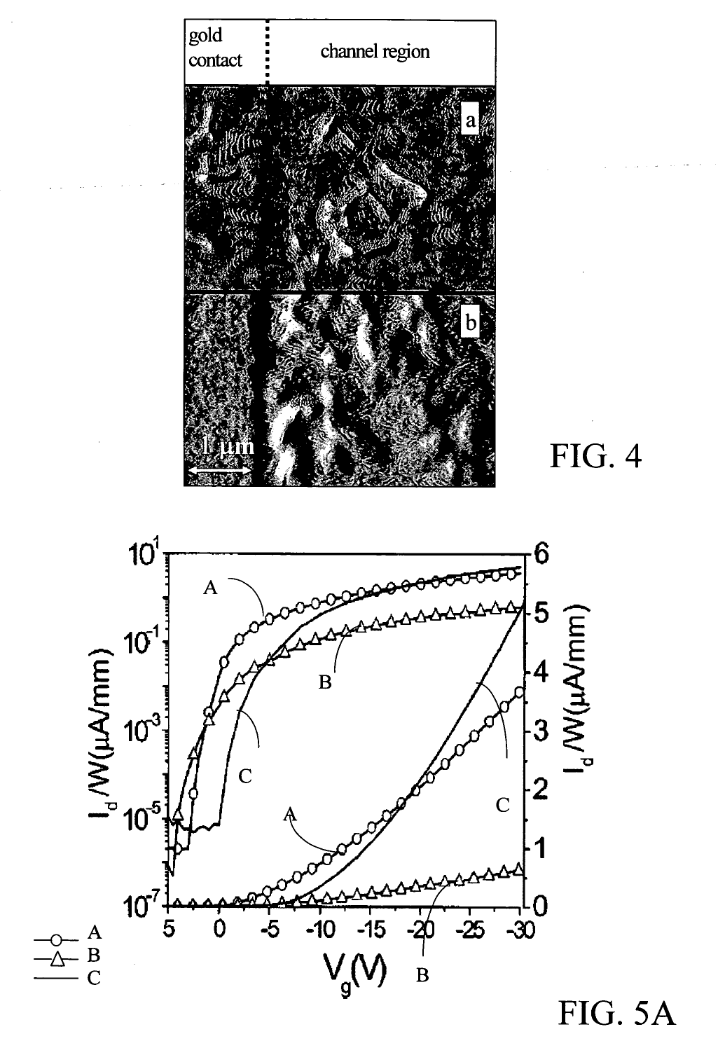

Referring to FIG. 4, atomic force microscope (AFM) micrographs of pentacene layer films, evaporated with (a) and without (b) a PMMA thin buffer layer 31, shows the edge between a gold contact (for the BC configuration) and a thin-film transistor channel region.

AFM measurements show that the pentacene film, grown on a SiO₂ surface, exhibit a very good polycrystalline structure, with a characteristic “terrace” structure with a 1.6-nm step. However, referring to FIG. 4, section (b), the film grown without PMMA becomes amorphous on top of gold contact producing a transitional region between the amorphous and polycrystalline structure, located just at the edge of the metal contact. On the contrary, referring to FIG. 4 section (a), the presence of a PMMA thin buffer layer 31 produces a continuous polycrystalline structure over both channel and metal contact regions.

In addition, AFM measurements on a wide number of samples show that the rms roughness of gold contacts (about 0.6 nm) is not appreciably modified by the presence of the PMMA thin buffer layer 31, indicating that no planarization effects are achieved for the used PMMA thickness.

It is thus clear that the role of the PMMA layer is primarily to allow an ordered pentacene growth by inhibiting the direct interaction of the π-conjugated pentacene system with metal or SiO₂ surfaces.

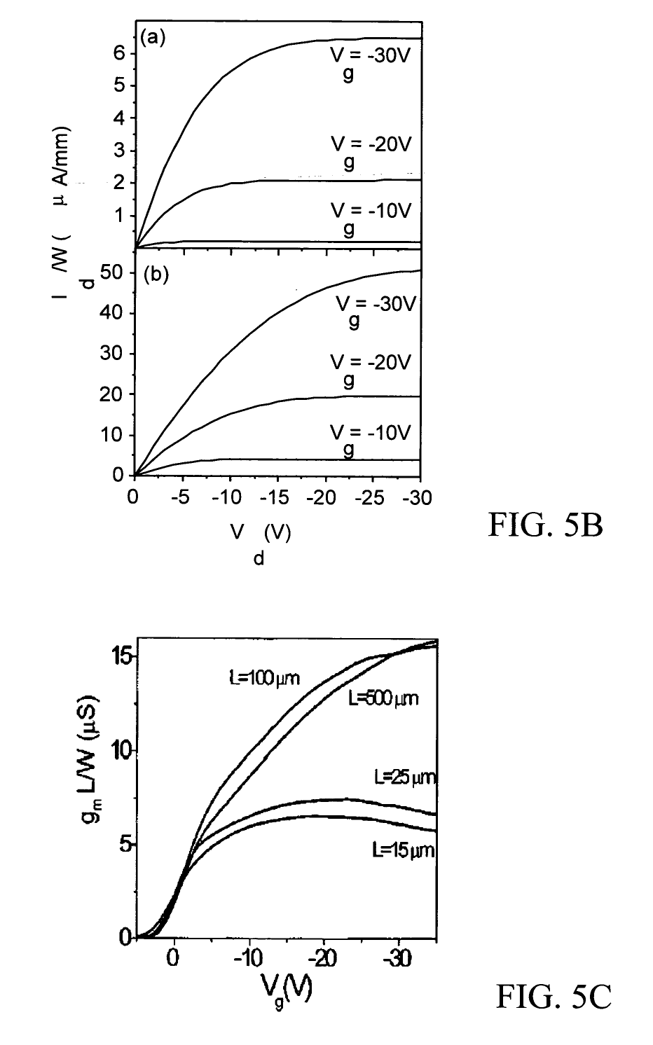

Referring to FIG. 5A, transfer characteristics, measured in vacuum and at Vd=−1 V, of pentacene-thin-film transistors having a BC configuration with (line A) and without (line B) a PMMA thin buffer layer 31 are shown. Also shown is the characteristic of a thin-film transistor having a TC configuration and comprising a PMMA thin buffer layer 31 (solid line C). Channel length is L=100 μm, and channel width is W=200 μm for all devices.

From the experimental data, a field-effect mobility μ_{FE}=0.65 (0.13) cm²/Vs, a subthreshold slope (measured at the onset of subthreshold region) of 0.57 (0.64) V/dec, a threshold voltage Vth=−6 (−5) V, and an on/off current ratio of 10⁶ (10⁶) can be estimated for devices with (without) the PMMA thin buffer layer 31.

In particular, it should be emphasized that O-TFT devices including a PMMA buffer layer according to an embodiment of the invention show parameters comparable to the best values reported for pentacene-based thin-film transistors according to the prior art. The main parameters of a group of representative devices are summarized in the following Table I, the devices having been measured at Vds=−1 V (W=200 μm, dox=130 nm, for all devices).

TABLE I

| | | | Subthre. | | |
|---|---|---|---|---|---|
| | L | μ | Slope | V_{T} | |
| Device | (μm) | (cm²/V s) | (V/dec) | (V) | Ion/Ioff |
| | 15 | 0.25 | 0.75 | −1.0 | 3 × 10⁶ |
| | 25 | 0.30 | 0.70 | −3.0 | 3 × 10⁶ |
| | 100 | 0.65 | 0.57 | −6.0 | 10⁶ |
| BC with | 500 | 0.65 | 0.61 | −8.5 | 2 × 10⁵ |
| PMMA | | | | | |
| BC without | 100 | 0.13 | 0.64 | −5.0 | 10⁶ |
| PMMA | | | | | |
| TC with | 100 | 1.40 | 0.71 | −12 | 10⁶ |
| PMMA | | | | | |

It should be noted that no significant difference can be observed between the mobility values deduced from the saturation regime (Vd=Vg) and the value obtained from the linear regime (Vd=−1 V).

Moreover, a good linear behavior at low Vd is observed, suggesting an efficient hole injection from the PMMA/Au contacts; in particular, referring to FIG. 5B, the output characteristics with (b) or without (a) a PMMA thin buffer layer 31 (reported for L=100 μm and W=200 μm) are shown.

Also, referring to FIG. 5C, the normalized transconductance vs gate voltage for different channel lengths L=15, 25, 100, 500 μm, for a pentacene thin-film transistor having a TC configuration and including a PMMA thin buffer layer 31 is shown.

It can be seen that the electrical characteristics do not show the correct scaling for short L, while for L>25 μm the correct scaling is observed. This behavior can be caused by the series resistance induced by the PMMA thin buffer layer 31, indeed for small value of L, the channel resistance becomes comparable to parasitic resistance related to the transport through the PMMA thin buffer layer 31 itself.

To optimize the resistance of the PMMA thin buffer layer 31, different devices have been manufactured by changing the annealing temperature (90/180° C.) and the thickness (8/30 nm) of the PMMA thin buffer layer 31 indeed. The PMMA resistance increases with the increasing annealing temperature and thickness, and it has been discovered that an optimized value of the annealing temperature is 90° C. with a layer thickness of 8 nm: these conditions are a good compromise to get low series resistance while still having a continuous and homogeneous PMMA film.

However, by improving the control of PMMA film thickness, it could be still possible to further decrease the PMMA series resistance by reducing film thickness.

In order to better understand the influence of the series resistance induced by the PMMA layer, O-TFT devices have been realized in both bottom and top contact configuration, codepositing on the two types of substrates the same PMMA thin buffer layer 31 and pentacene layer 6. The transfer characteristics are compared in FIG. 5A and it can be seen that the O-TFT device having a TC configuration exhibits a μ_{FE}=1.4 cm²/Vs, a subthreshold slope of 0.71 V/dec, and a Vₜₕ=−12 V, with a lower current in the subthreshold region, if compared to a O-TFT device having a BC configuration, in spite of the PMMA parasitic resistance present in the BC configuration.

This is quite surprising, especially considering that the oxide/PMMA/pentacene interfaces in the channel region of both devices are expected to be the same, as they have been cofabricated, and that, for a given Vg, the same amount of holes should be present in the channels of the two thin-film transistors.

This reduced current in the O-TFT device having a TC configuration is probably due to the effect of the series resistance induced by the vertical transport through the pentacene film and/or the pentacene/Au contact. As the gate voltage is increased in modulus, hole accumulation expands towards the back-channel region, decreasing pentacene vertical resistance as well as contact resistance.

In this case, the subthreshold region of O-TFT devices having a TC configuration is not controlled by the channel resistance, as also suggested by the known pentacene-film-thickness dependence of the electrical characteristics. On the contrary, above a threshold voltage value, such O-TFT devices having a TC configuration show higher on current, if compared to O-TFT devices having a BC configuration, suggesting that in this regime the PMMA series resistance limits the on current while the gate-controlled parasitic resistance in the O-TFT devices having a TC configuration becomes negligible. This last effect is confirmed by the correct L scaling of the on current in the O-TFT devices having a TC configuration.

In conclusion, an improved O-TFT device has been provided by using a polymethylmetacrylate (PMMA) layer as buffer layer between an organic active layer, in particular a pentacene layer.

The pentacene-thin-film transistor including the PMMA thin buffer layer shows very good performances both in BC and TC configuration.

Advantageously, the PMMA thin buffer layer 31 can be used in order to obtain a good interface quality between pentacene and SiO₂ or Au layers, while still allowing good ohmic contact.

In particular, the realized O-TFT devices in the BC and TC configurations exhibit mobility, on/off current ratio, threshold voltage, and subthreshold slope values among the best reported in literature.

Finally, it should be pointed out that, advantageously according to an embodiment of the invention, the polymethylmetacrylate (PMMA), also known as Plexiglass, most often used as electronic resist, is one of the most common plastic material in electronics, thanks to a low-cost, low-temperature process, high stability, and easy processing.

Organic thin film transistors having the structure and formed according to the described embodiments of the present invention can be utilized in a variety of different types of electronic devices, such as memory devices, computer systems, communications devices such as cellular phones, personal digital assistants, and so on.

From the foregoing it will be appreciated that, although specific embodiments of the invention have been described herein for purposes of illustration, various modifications may be made without deviating from the spirit and scope of the invention.

What is claimed is:

1. An organic thin-film transistor device integrated on a substrate and comprising at least an organic active layer and metallic contact regions realized on an insulating layer wherein it further comprises a thin buffer layer of polymethylmetacrylate or PMMA realized between the metallic contact regions and the organic active layer.

2. The organic thin-film transistor device of claim 1, further comprising:
a thick oxide protective layer formed on the substrate,
a gate region formed on the thick oxide protective layer,
the insulating layer being a gate insulating layer covering both the gate region and the thick oxide protective layer.

3. The organic thin-film transistor device of claim 2, wherein the metallic contact regions are realized on the gate insulating layer, spaced apart from each other and defining therebetween an intermediate region of the gate insulating layer and the organic active layer is deposited on the metallic contact regions, as well as on the intermediate region.

4. The organic thin-film transistor device of claim 2, wherein the organic active layer is deposited on the gate insulating layer and the metallic contact regions are realized on the organic active layer.

5. The organic thin-film transistor device of claim 1, wherein the thin buffer layer has a thickness between 5 and 10 nm, preferably 8 nm.

6. The organic thin-film transistor device of claim 5, wherein the thin buffer layer is obtained by a film of PMMA 950 K annealed at 90° C. for 10 min.

7. The organic thin-film transistor device of claim 5, wherein the thin buffer layer is obtained by spinning a layer of PMMA and annealing it at 90° C. for 10′.

8. The organic thin-film transistor device of claim 1, wherein the organic active layer is a pentacene layer.

9. The organic thin-film transistor device of claim 7, wherein the pentacene layer is made by evaporation.

10. A process for manufacturing an organic thin-film transistor device on a substrate comprising the following steps:
formation of an insulating layer over the substrate;
definition of metallic contact regions over the insulating layer, and
formation of an organic active layer over the insulating layer,
wherein it further comprises a step of integration of a thin buffer layer of polymethylmetacrylate or PMMA realized between the metallic contact regions and the organic active layer.

11. The process of claim 10, further comprising the steps of:
formation of a thick oxide protective layer on the substrate, the thick oxide protective layer acting as a mechanical, electrical and thermal insulation element for the substrate itself;
formation of a gate region on the thick oxide protective layer, and
formation of a gate insulating layer as the insulating layer, the gate insulating layer covering both the gate region and the thick oxide protective layer.

12. The process of claim 11, wherein the step of definition of metallic contact regions further comprises the step of forming the metallic contact regions on the gate insulating layer, spaced apart from each other and defining therebetween an intermediate region of the gate insulating layer and wherein the step of formation of the organic active layer further comprises a step of deposition of the organic active layer on the metallic contact regions, as well as on the intermediate region.

13. The process of claim 11, wherein the step of formation of the organic active layer further comprises a step of deposition of the organic active layer on the gate insulating layer and wherein the step of definition of metallic contact regions further comprises the step of forming the metallic contact regions on the organic active layer.

14. The process of claim 10, further comprising an annealing step at 120° C. for 30′ and a cleaning step in HF:H₂O=1:80 for 5″ before the step of integration of the thin buffer layer.

15. The process of claim 10, wherein the step of integration of the thin buffer layer comprises a spinning step wherein a layer having a thickness of 5-10 nanometers is formed, followed by an annealing step at 90° C. for 10′.

16. The process of claim 10, wherein the step of formation of the organic active layer comprises a step of growing a pentacene layer Sigma Aldrich 97% on the thin buffer layer.

17. The process of claim 16, wherein the step of formation of the organic active layer comprises an evaporation step.

18. The process of claim 17, wherein the evaporation step has an evaporation rate of 0.5-5 nm/min, preferably 3 nm/min with a vacuum pressure of 3*10⁻⁶ mbar.

19. The process of claim 11, further comprising, before the step of formation of the thick oxide protective layer, a step of cleaning the substrate to remove any contaminants or undesired particles.

20. The process of claim 1, wherein the step of formation of the thick oxide protective layer comprises a ECR-PECVD step at 250° C.

21. The process of claim 11, wherein the step of formation of the gate region comprises a step of deposing a metallic layer followed by a step of patterning the metallic layer in order to form the gate region.

22. The process of claim 11, wherein the step of formation of the gate insulating layer comprises a step of deposition of a dielectric material, with a thickness of at least ten nanometers.

23. The process of claim 11, wherein the step of formation of the gate insulating layer comprises a step of deposition of an organic layer, with a thickness of at least ten nanometers.

24. The process of claim 11, wherein the step of definition of metallic contact regions further comprises a step of deposition by sputtering or evaporating of a metal layer with a thickness of at least ten nanometers on the gate insulating layer, followed by an optical lithography and a wet attack steps.

25. The process according to claim 10, wherein any thermal steps are carried out at a lower temperature than a damage temperature of the substrate.

26. An organic thin-film transistor, comprising:
a gate region;
source and drain contact regions;
a gate insulating layer formed between the gate region and the source and drain contact regions;
an organic active layer formed between the source and drain contact regions; and
a thin buffer layer of polymethylmetacrylate (PMMA) formed between the organic active layer and each of the source and drain contact regions.

27. The organic thin-film transistor of claim 26 wherein the transistor has a bottom-contact configuration.

28. The organic thin-film transistor of claim 26 wherein the transistor has a top-contact configuration.

29. The organic thin-film transistor of claim 26 wherein the organic active layer comprises a pentacene layer.

30. The organic thin-film transistor of claim 26 wherein the source and drain contact regions comprise metal regions.

31. An electronic device, comprising:
electronic circuitry containing an organic thin-film transistor, the transistor including,
a gate region;
source and drain contact regions
a gate insulating layer formed between the gate region and the source and drain contact regions;
an organic active layer formed between the source and drain contact regions; and
a buffer layer of polymethylmetacrylate (PMMA) formed between the organic active layer and each of the source and drain contact regions.

32. The electronic device of claim 31 wherein the electronic circuitry comprises one of memory, computer, and communications circuitry.

33. A method of manufacturing an organic thin-film transistor, the method comprising:
forming a gate region;
forming an insulating layer adjoining the gate region;
for a bottom-contact configuration organic thin-film transistor,
forming spaced apart source and drain contact regions on the insulating layer, with an exposed portion of the insulating layer between adjacent source and drain regions defining an intermediate region that is positioned adjacent the gate region;
forming a thin buffer layer of polymethylmetacrylate (PMMA) on the source and drain contact regions and the intermediate region; and
forming an organic active layer on the thin buffer layer; and
for a top-contact configuration organic thin-film transistor,
forming an organic active layer on the insulating layer;
forming a thin buffer layer of polymethylmetacrylate (PMMA) on the organic active layer; and
forming spaced apart source and drain contact regions on thin buffer layer, with an intermediate region being defined between adjacent source and drain regions, the intermediate region being positioned adjacent the gate region.

34. The method of claim 33 wherein the source and drain contact regions each comprise metal regions.

35. The method of claim 33 wherein the organic active layer comprises a pentacene layer.
